(19) United States
(12) Patent Application Publication
(10) Pub. No.: US 2012/0199857 A1
(43) Pub. Date: Aug. 9, 2012

(54) Wafer-Scale Emitter Package Including Thermal Vias

(75) Inventors: Giles Humpston, Buckinghamshire (GB); Moshe Kriman, Tel-Aviv (IL); Marc Himel, Winter Springs, FL (US)

(73) Assignee: DIGITALOPTICS CORPORATION EAST, Charlotte, NC (US)

(21) Appl. No.: 13/500,889

(22) PCT Filed: Oct. 7, 2010
(86) PCT No.: PCT/US10/51871

§ 371 Date: Apr. 6, 2012

Related U.S. Application Data
(60) Provisional application No. 61/249,569, filed on Oct. 7, 2009.

(51) Int. Cl. H01L 27/15; H01L 33/64

(52) U.S. Cl. 257/89; 438/33; 257/E27.12; 257/E33.075

(57) ABSTRACT

Improved packages for light emitters may be fabricated at the wafer level. The package can be a single device or an array of die. The package includes a thermal via that extends through the thickness of the package substrate. The thermal via may be made of a material possessing a high thermal conductivity. The thermal via may be wider at the package exterior than at the interior to provide heat spreading between the device and its heat sink. The taper angle of the thermal via may be around 45 degrees to match the natural spread of heat in a solid. The thermal via may extend above the package interior, so its height is sufficient to position an emitter placed thereon at one foci of a parabola, where the vertex of the parabola is at the surface of the package substrate from which the thermal via extends.

### FIELD OF THE INVENTION

The present invention relates to the manufacture of packages for light-emitting diodes (LEDs) and other fabricated electronics.

### BACKGROUND

A light-emitting diode (LED) is a two-terminal semiconductor device that emits light when biased in the forward direction. Many billions of LEDs are manufactured each year. The light emitted can range from narrow band spectra anywhere in the range from long wavelength infrared to short wavelength ultraviolet radiation and wide band spectra that encompass the whole visible spectrum (i.e., white light).

A LED does not emit light uniformly from over the die area. Instead, the light emerges from the semiconductor in a number of so-called ‘escape cones’. Theoretically, six escape cones are possible for a point light source in a rectangular transparent LED chip, including the top, four sides, and bottom of the LED. Light generated outside the escape cone angle is reflected internally and absorbed as heat. Only about 5-10% of the photons generated can escape from a bare LED die. However, by using techniques such as high refractive silicone encapsulant, chip shaping, die underside minoring, die surface texturing and photonic band gap structures, the escape efficiency can be greatly boosted.

In common with most light sources, LEDs do not efficiently convert the electricity into photons. The inefficiency is manifest as heat that serves to raise the temperature of the die. Unfortunately, the efficiency of LEDs decreases rapidly with rising temperature, so poor thermal control can rapidly lead to destruction of the semiconductor device. Consequently, great care needs to be taken in the design and use of LEDs to ensure efficient extract of heat from the die and its dissipation in a suitable heat sink.

Because LEDs are semiconductor devices, they require protection from the environment to ensure their longevity. Some form of device package is therefore required. Many different types of package specifically designed for LEDs exist. In addition to providing the traditional package functions of environmental protection and electrical interconnects, where possible the packages are engineered to further provide some degree of optical function and thermal management. This integrated approach is more economic than having separate components for each purpose.

As might be expected, packages for LEDs that are required to provide multiple functions are a compromise between cost, complexity, and performance. For example, discrete packages for LEDs are generally able to achieve good performance metrics but tend to be physically large and entail complex assembly processes. A further disadvantage of discrete packages is that the cost of manufacture rises incrementally with each package produced, so that doubling the production volume does not produce significant piece-part cost reduction. Improvements in LED packaging would be desirable.

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

### SUMMARY

Improved packages for light emitters may be fabricated at the wafer level. The package can be a single device or an array of die. The package can house any optically or near-optical responsive components, including LEDs, lasers, Micro-Electrical-Mechanical Systems (MEMS) and electronic devices like Electrically Erasable Programmable Read-Only Memories (EEPROMs). The package substrate may be made of silicon.

In one or more embodiments, the package includes a thermal via that extends substantially through the thickness of the package substrate. The thermal via may be made of a material possessing a high thermal conductivity, including, for example, copper, aluminum, silver, or gold. The thermal via may be wider at the package exterior than at the interior to provide heat spreading between the device and its heat sink. The taper angle of the thermal via may be around 45 degrees to match the natural spread of heat in a solid. In one embodiment, the thermal via extends above the package interior. In one embodiment, the interior height of the thermal via is sufficient to position an emitter placed thereon at one foci of a parabola, where the vertex of the parabola is at the surface of the package substrate from which the thermal via extends.

In one or more embodiments, the package includes a spacer that surrounds the emitter. In one embodiment, the face of the spacer that faces the emitter is inclined at an angle. In one embodiment, the average angle of inclination is around 45 degrees. In another embodiment, the profile of the inclination is substantially a parabola. In one embodiment, the spacer is a molded wafer of liquid crystal polymer. In one embodiment, the spacer is coated with a reflective material or structure that is reflective at the wavelengths of interest.

According to other embodiments, the package includes a package cover. The package cover may provide mechanical and environmental protection to the emitter. Further, the package cover may provide a beam-shaping action, which includes, but is not limited to, refractive, diffractive or combinational refractive/diffractive, a Fresnel lens, or contains an index matching or a wavelength conversion material like a phosphor or quantum dot.

The emitter package die may be flip-chip mounted inside the package or attached to a thermal via and connected to lands by wire bonds. In one embodiment, a redistribution layer provides electrical pathways to package contacts. For front side contacts, contacts on the front face of the package are provided by lands on the package substrate. For underside contacts, interconnections are provided by through silicon via interconnects. Edge connect and wrap around contacts are also contemplated.

### BRIEF DESCRIPTION OF THE DRAWINGS

In the drawings:

FIG. 1 shows section and plan views showing two components of a wafer-scale package for LEDs.

FIG. 2 shows section and plan views showing three components of a wafer-scale package for LEDs.

FIG. 3 illustrates one process flow for creating the wafer-scale LED package substrate.

FIG. 4 shows section and top plan views of wafer-scale package for LEDs illustrating the benefit of a shaped and reflective spacer surrounding the die in improving light extraction efficiency and beam management.

FIG. 5 shows a section view of wafer-scale package for LEDs, including a shaped and reflective spacer surrounding the die and a polymer lid that provides encapsulation, index matching and/or wavelength conversion and optionally beam management.

FIG. 6 shows a section view of wafer-scale package for LEDs closed by a lid wafer that has structures providing optical functionality.

FIG. 7 shows an embodiment where the LED is located at one foci of the parabola formed by the shaped and reflective spacer, by extending the thermal via above the substrate surface in the form of a post.

FIG. 8 shows a section and top plan view of a wafer-scale package for LEDs with package lands accessible from the front face.

FIG. 9 shows an embodiment where the package includes both front and underside contacts.

FIG. 10 shows a general process flow for packaging LEDs or other light emitters in accordance with embodiments herein.

FIG. 11 shows an embodiment of an emitter package that includes top side edge connects and vias leading to underside ball grid array (BGA) contacts.

FIG. 12 shows isometric figures of an embodiment of an emitter package that includes underside contacts.

FIG. 13 shows isometric figures of an embodiment of an emitter package that includes top side contacts.

FIG. 14 shows an embodiment of an emitter package with shaped, reflective sidewalls and redistribution layer to an array of a plurality of emitters.

FIG. 15 shows an embodiment of an emitter package with a phosphor-polymer lens and top-side edge and underside contacts.

FIG. 16 shows an embodiment of an emitter package with an elevated emitter.

FIG. 17 shows an embodiment of an emitter package where electrical connectivity is established through a combination of a wire bond and a redistribution layer (RDL).

FIG. 18 shows an embodiment of an emitter package where the emitter sits substantially flush with a top surface of the substrate wafer and electrical connectivity is established solely with a wire bond to an electrical through silicon via.

FIG. 19 shows a first step in a process for manufacturing a wafer level emitter package with integral thermal vias.

FIG. 20 shows the process continuing with the temporary bonding of conductive material to a temporary carrier using a temporary adhesive.

FIG. 21 shows a resist layer being applied on top of the conductive material.

FIG. 22 shows the resist layer being removed and an optional passivation layer being applied onto the etched conductive material.

FIG. 23 shows a silicon substrate being processed in parallel to the process steps shown in FIGS. 19-22.

FIG. 24 shows the conductive material wafer bonded to the substrate wafer with the substrate pillars staggered relative to the conductive pillars.

FIG. 25 shows the substrate wafer being polished or removed by a grinder or polisher.

FIG. 26 shows a subsequent etching of the substrate material producing a particular configuration where conductive plugs extend above a top surface of bulk substrate material.

FIG. 27 shows an individual die being singulated using dicing, ablating, or laser cutting techniques.

### DETAILED DESCRIPTION

In the following description, for the purposes of explanation, numerous specific details are set forth in order to provide a thorough understanding of the present invention. It will be apparent, however, that the present invention may be practiced without these specific details. In other instances, well-known structures and devices are shown in block diagram form in order to avoid unnecessarily obscuring the present invention.

Wafer-scale manufacture of components is economically a highly attractive alternative to discrete assembly. In wafer-scale manufacture, a two-dimensional array of parts is processed as a unitary assembly. The materials and process costs are therefore shared among the good parts on the wafer. Because LEDs are small, many thousands of LED packages will fit comfortably on a wafer. Dicing of the wafer yields fully formed individual packages that are often substantially lower in cost compared with discrete packages.

Embodiments described herein provide a package, fabricated at the wafer-scale. Although certain embodiments are intended for LEDs, the packaging techniques could equally be used for other types of devices including lasers, MEMS or any type of device that has optical functionality. As used herein, the term optical is taken to be the portion of the electromagnetic spectrum between the far infra-red and the near ultra-violet. In at least some embodiments, the package consists of a substrate that may be in the form of a wafer manufactured to Semiconductor Equipment and Materials International (SEMI) standards so as to be compatible with semiconductor industry processing tools. In some embodiments, the wafer will be made of mechanical-grade silicon, but could also be glass, ceramic, polymer or even metal.

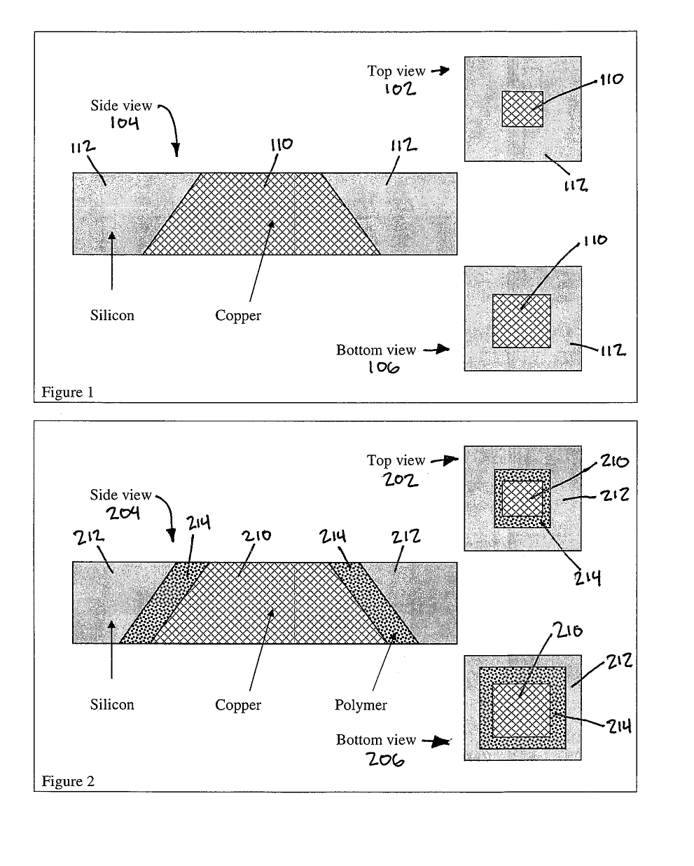

Through the thickness of the substrate is formed an array of frusto-conical through holes, one hole corresponding to the location of each LED, or group of LEDs where a single package is required to contain multiple devices as, for example, in a tri-color or ‘RGB’ light engine. The narrow portion of the through hole therefore must be larger in area than the LED or LEDs that will eventually be sited in that region of the package. The through hole is preferably made with side walls that slope at between 30 and 60 degrees and preferably around 45 degrees for two reasons. These are, firstly, that through holes with sloping side walls are generally cheaper to manufacture than holes with vertical side walls since the etch rates that can be achieved are greatly superior. The machine-time and cost concomitantly is reduced. Secondly, the primary function of this component of the package is as a means of extracting heat from the die and transporting it to a heat-sink. The thermal transport mechanism is by conduction so that a side wall slope of around 45 degrees matches the natural dispersion of heat as it passes through the package. To provide maximum thermal conductivity, the frusto-conical holes are filled with a material of high thermal conductivity and low cost, with copper and aluminum and alloys thereof being suitable choices. More costly alternatives may include silver and gold or alloys thereof. At this stage the package will resemble the structure shown in FIG. 1. FIG. 1 shows section and plan views showing two components of a wafer-scale package for LEDs. These views include top view 102, side view 104, and bottom view 106. A material of high thermal conductivity forms a tapered via 110 through the silicon substrate 112 for each LED or group of LEDs in a multi-die package.

It may be the case, in some embodiments, that the filled frusto-conical vias need to be electrically isolated from the wafer substrate. Also, in certain embodiments, there will be a difference in thermal expansion coefficient between the high thermal conductivity material and the wafer substrate material. This is particularly the case when the former is a metal and the latter is silicon. Direct bonding could result in high stresses being generated that might lead to premature failure of the package. A solution to both of these requirements is provided by an insulation layer located between the metal and the wafer. The insulating material may comprise polymers, plastics, rubber, silicone, or other suitable materials. Depending on the desired function, the material may be a dielectric material and may be compliant (e.g., exhibit large plastic strain). Hence, the material may provide electrical isolation and be easily deformed, while having the ability to absorb static and cyclic strain without damage. The package substrate then appears as shown in FIG. 2. Specifically, FIG. 2 shows section and plan views showing three components of a wafer-scale package for LEDs. These views include top view 202, side view 204, and bottom view 206. A polymer 214 provides electrical isolation and absorbs strain between the thermal via 210 and the silicon wafer 212.

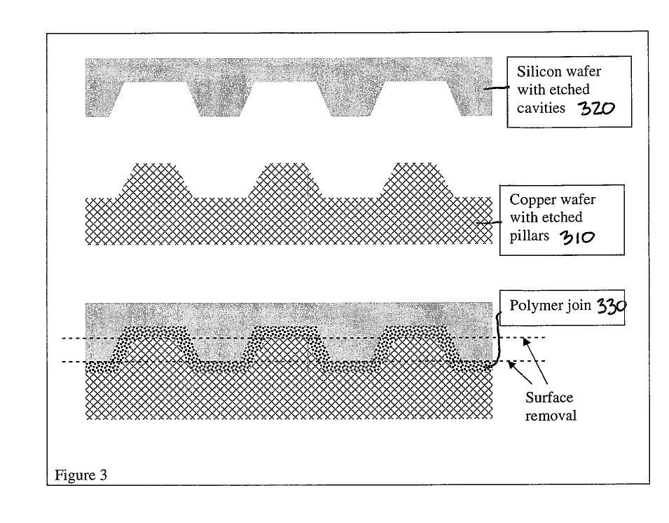

An embodiment of this structure is achieved by fabricating the package as two wafer-scale components that are then mated together. As an example, one component could be a wafer of copper. Certain areas of the copper are removed, for example by wet etching, to leave a regular array of copper pillars (see FIG. 3). FIG. 3 illustrates one process flow for creating the wafer-scale LED package substrate. A copper wafer 310 with etched pillars is shown. Because the pillars were formed by subtraction from a wafer they will be substantially the same height. The same structure could be developed by a build-up process, where the pillars are grown from a metal substrate, but height control is more difficult in this approach, likely requiring an additional planarising operation. Alternatively, the metal wafer may be fabricated using conventional metal fabrication techniques, including, for example, machining or casting. The second component is a silicon wafer 320. The silicon wafer is etched, for example by a plasma process, to leave a full-thickness wafer containing an array of blind apertures or through holes. The geometry and pattern of the metal pillars is designed to match the holes/apertures in the silicon wafer. Aligning and joining of these two components with a polymer 330, followed by optional removal of surface material, will yield the desired substrate structure for the wafer level package. This step is optional since in some instances there may be advantages to the thermal performance of the package in having the entire underside a slab of copper that is in intimate contact with the thermal via.

The LED die has finite thickness, so that, when attached to the top of the frusto-conical metal plug, it will stand above of the wafer surface. This means that, in one embodiment, the underside of the package lid is spaced a slightly greater distance from the substrate surface. This is accomplished by a spacer element that fills the gap. The spacer element may totally surround the LED so that it forms a continuous seal between the package lid and package substrate. The LED is then contained within a protective enclosure. Sufficient protection from the ambient environment is then obtained.

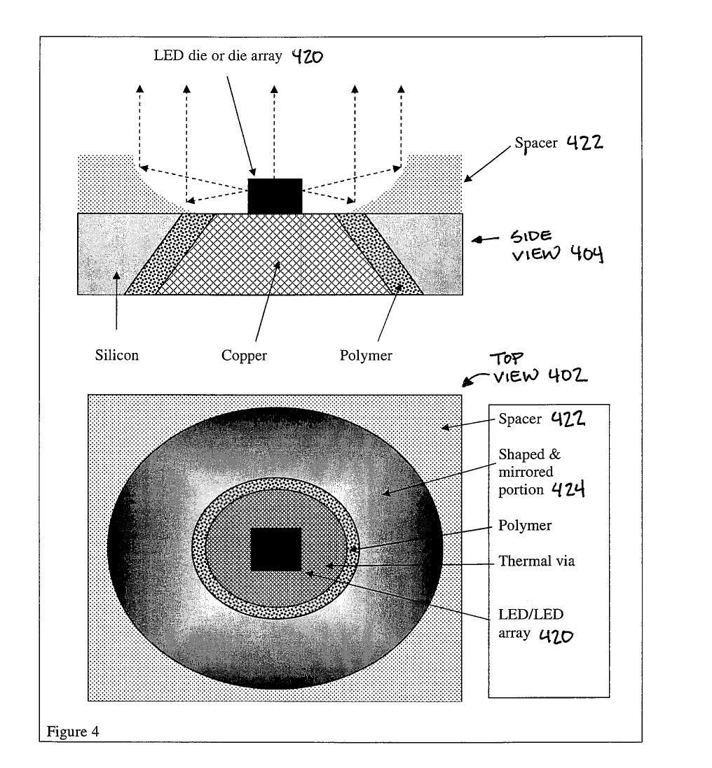

The spacer can be used to provide additional function. FIG. 4 shows section 404 and top 402 plan views of wafer-scale package for LEDs illustrating the benefit of a shaped and reflective spacer surrounding the die in improving light extraction efficiency and beam management. The role of the LED 420 is to convert electricity to photons. To achieve high efficiency, the package should desirably be engineered to liberate as many as possible of the photons emitted by the LED. By setting the interior faces of the package spacer 422 at an inclined angle, photons emitted in the horizontal plane by the LED will tend to be reflected towards the package opening. Best performance will be obtained when the spacer walls are suitably angled. For a straight surface this means at an angle of close to 45 degrees. However, greater efficiency and better intensity distribution over the beam area are accomplished if the sidewalls more closely resemble a parabola where the LED is at the foci. This shape can be realized from a sidewall formed from a molded polymer, such as liquid crystal polymer (LCP). Alternatively, isotropic etching of many metals through a single aperture mask will yield a plate containing through holes that are close to a parabola in profile. In other embodiments, the sidewalls may be formed using mechanical means, such as molding, machining, and polishing. An LED package substrate with shaped sidewalls is depicted in FIG. 4.

For reasons of cost and ease of manufacture, spacer 422 is preferably made of a polymeric material. Polymers are generally permeable to various species and usually not highly reflective towards the portion of the electromagnetic spectrum emitted by LEDs. Therefore, another embodiment of the invention contemplates coating of the spacer sidewalls with a material or structure 424 that is highly reflective at the wavelength of interest and preferably impermeable. Examples include aluminum, silver and Bragg minors.

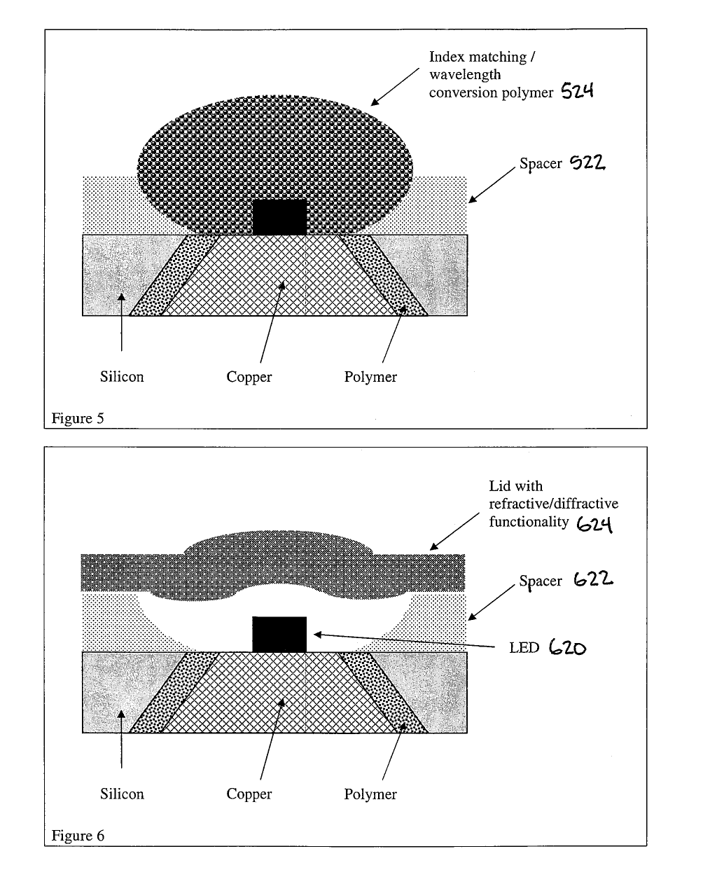

In one embodiment, each package is closed by a lid that can take a number of forms. For example, the package cover can be a polymer that totally encapsulates the die and completely fills the package well as shown in FIG. 5. Specifically, FIG. 5 shows a section view of wafer-scale package for LEDs, including a shaped and reflective spacer 522 surrounding the die and a polymer lid 524 that provides encapsulation, index matching and/or wavelength conversion and, optionally, beam management. In this instance, the polymer will usually be chosen on the basis of either its index matching characteristics and/or its ability to facilitate wavelength conversion. Index matching increases the photon extraction efficiency, while wavelength conversion makes it possible to produce white light from high efficiency blue and ultra-violet LEDs. Optionally, this polymer can be shaped to provide refraction of the light and management of the emitted beam.

In another embodiment shown in FIG. 6, which embodiment can be used in conjunction with the preceding embodiments, the package lid can be a plate of material that is transparent at the wavelength of the radiation produced by the LED 620. In particular, FIG. 6 shows a section view of wafer-scale package for LEDs closed by a lid wafer 624 that has structures providing optical functionality. Spacer 622 is also shown. For LEDs that radiate in the visible spectrum the plate will typically be made of glass. For an infra-red LED, the plate could be made of silicon or germanium. The glass package cover need not be optically passive. For example, as is well known and understood, the technology exists to form features in the thickness of the glass that provide for refractive and diffractive functionality. Because the glass plate has two surfaces, both could be endowed with such features, say one refractive and the other diffractive. Other optical functions like apertures, anti-reflection coatings and baffles are also possible. Also, as is well known, it is possible to endow a flat transparent lid with optical functionality adding features on to its surfaces. Typically these will be made from polymeric materials and a wide variety of beam shaping functions can be realized including both refractive and diffractive functions as well as components like Fresnel lenses.

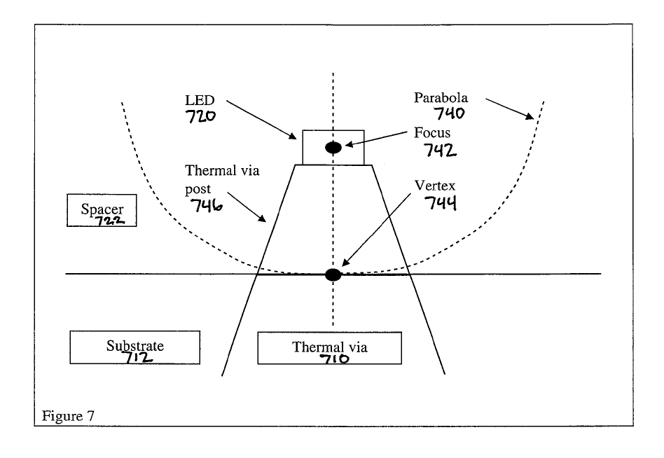

FIG. 7 shows an embodiment where the LED 720 is located at one focus 742 of the parabola 740 formed by the shaped and reflective spacer 722, by extending the thermal via 710 above the substrate surface 712 in the form of a post 746. As suggested above, the package spacers 722 may be shaped like a parabola 740 with the LED 720 at one of the foci 742. As is well known, the foci of a parabola is spaced a short distance from the vertex 744. Therefore an optional aspect of an embodiment of the invention is that the thermal plug 746 on which LED 720 resides can be made to protrude from an upper surface of substrate 712. This ensures that light from the LED escape cones that is radiated downward towards substrate 712 can be efficiently redirected towards the package opening. The result is an improvement in the electro-optic efficiency of the device.

LEDs are commonly manufactured with two bond pads, which are the electrical terminals of the device. To provide functionality, an electrical pathway is formed between these bond pads and other terminations on the exterior of the package. The electrical conductors may be routed through the package lid, spacer or substrate, or interfaces in between. The interconnects generally include properties of good electrical conductivity coupled with electrical isolation from the substrate wafer. These conditions are met by a metal conductor, surrounded on the relevant surfaces by a polymer or ceramic dielectric. Connection between the bond pads on the die and the conductive pathways through the wafer substrate can conveniently be made by wire bonds. Alternatively, the LED die can be provided with appropriate terminations and joined by flip-chip connections.

For interconnects that pass through the package substrate, both copper and aluminum are good conductors of electricity and heat. Therefore, the physical requirements of the electrical interconnects are essentially the same as those of the thermal via described earlier, the only major difference being that the interconnects can be much smaller in diameter yet still carry sufficient current to energize the LED. This similarity makes it possible to fabricate both the thermal and electrical passages through the substrate wafer at the same time using the same process steps, materials and equipment, to great benefit for the package cost. One such method results in structures available commercially as SHELLCASE® MVP interconnects and described in commonly assigned and co-pending patent application US 2009/0065907, the relevant contents of which are hereby incorporated by reference herein. Other through-silicon-via interconnects as are known in the art may be used. In some embodiments, interconnects are fabricated in the form of hollow pipes, to decrease the materials cost. However, it will be apparent to one of skill in the art that they could be filled with metal or other material to boost the electrical and in particular thermal conductivity of the electrical interconnects.

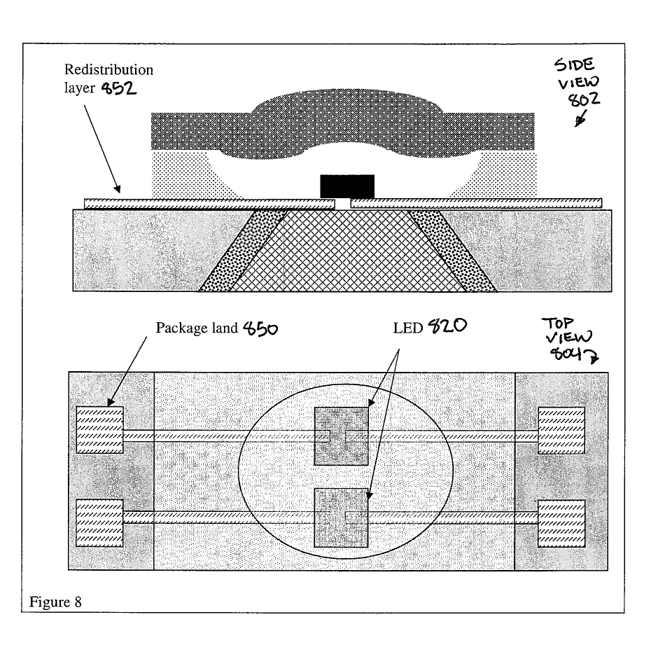

In some instances it may be desirable to have the package contacts accessible from the front face of the package. FIG. 8 shows a section 802 and top 804 plan view of a wafer-scale package for LEDs with package lands accessible from the front face. Indeed, some LED packages are provided with contacts on both the underside and the front face so the same package can be used in a wider variety of applications. An embodiment of the invention that permits both front face and front face plus underside contacts utilizes a package substrate that is larger than the spacer in plan area. The additional real estate can be provided with package lands 850 for exterior, front face, interconnects, as shown in FIG. 8. A redistribution layer 852 provides electrical pathways between the package lands and LED die 820 inside the package. Redistribution layer 852 is typically a multi-layer structure comprising dielectric and metal layers, the total assembly being or the order of one micron in height. This makes it easy for the redistribution layer to enter the package enclosure at the interface between the substrate and the sidewall without compromising the integrity of the structure.

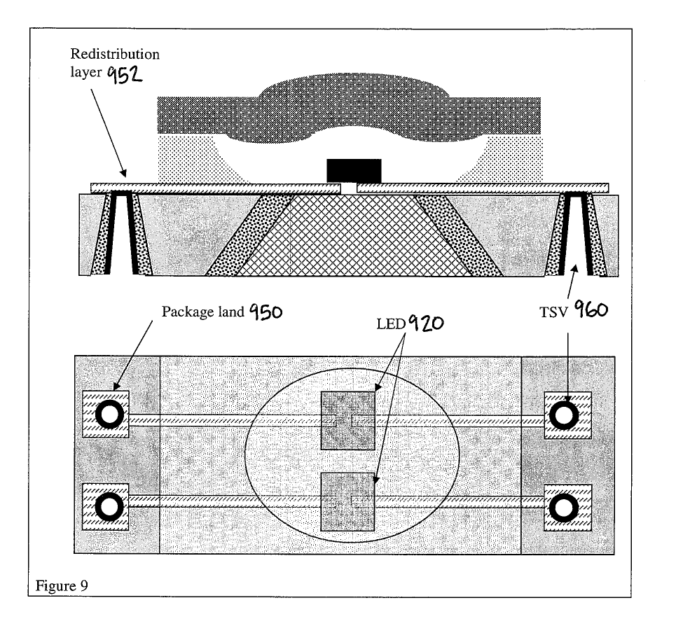

FIG. 9 shows an embodiment where the package includes both front and underside contacts. Alternatively, the through substrate interconnects can placed outside of the package. In that instance, the front face lands 950 could be used as catch pads for the through-silicon-via (TSV) interconnects 960. The advantage of this approach is that the package lands 950 will likely be quite large and hence the tolerances on lateral position of the through-silicon-vias can be relaxed. As a general rule, high precision is more expensive to achieve so relation in tolerance frequently delivers a reduction in cost. Redistribution layer 952 and LEDs 920 are again shown.

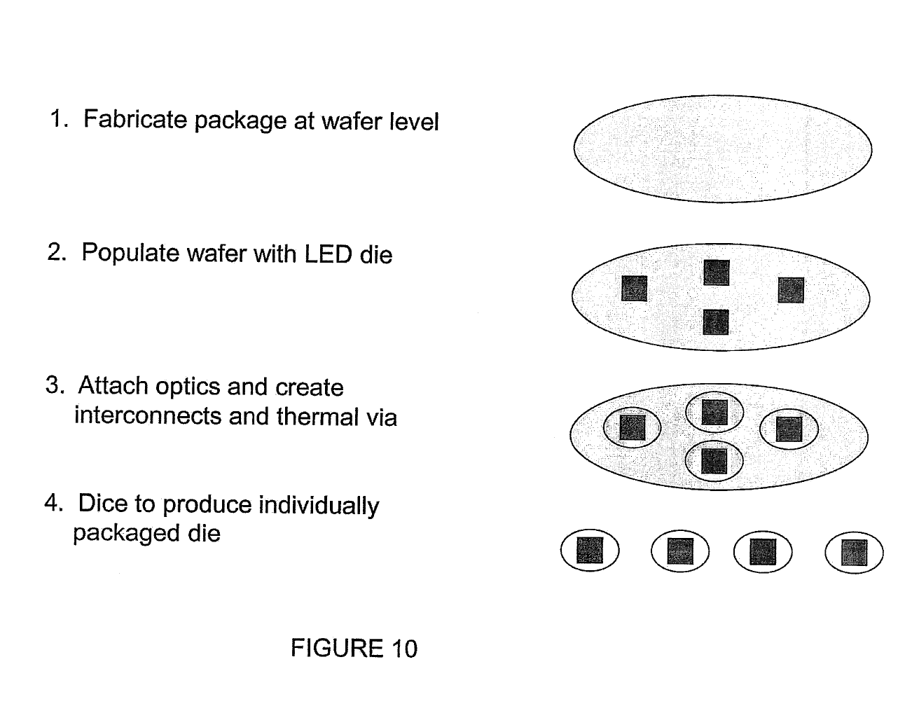

FIG. 10 shows a general process flow for packaging LEDs or other light emitters in accordance with embodiments herein. In a first step, a substrate wafer is provided upon which LED die are populated. Next, the electrical interconnects, thermal vias, and optics are formed at each die location. Ultimately, the individual dies are singulated to produce individually packaged dies.

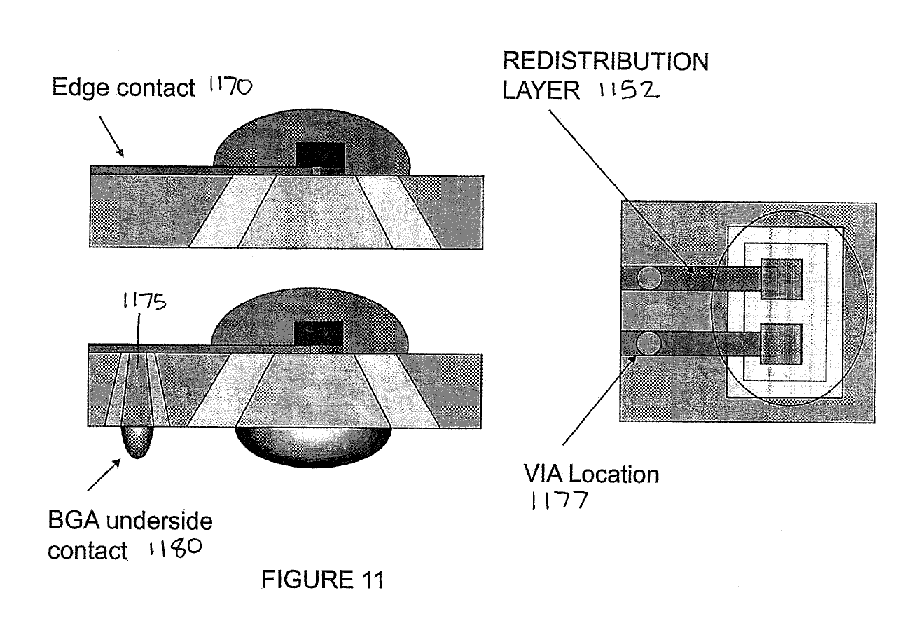

FIG. 11 shows an embodiment of an emitter package that includes top side edge contacts 1170 and vias 1177 leading to underside ball grid array (BGA) contacts 1180. In contrast to the embodiment shown in FIG. 9, this particular embodiment shows the electrical vias are filled with a solid conductive material 1175. Further, the redistribution layer 1152 is coupled directly to the emitters.

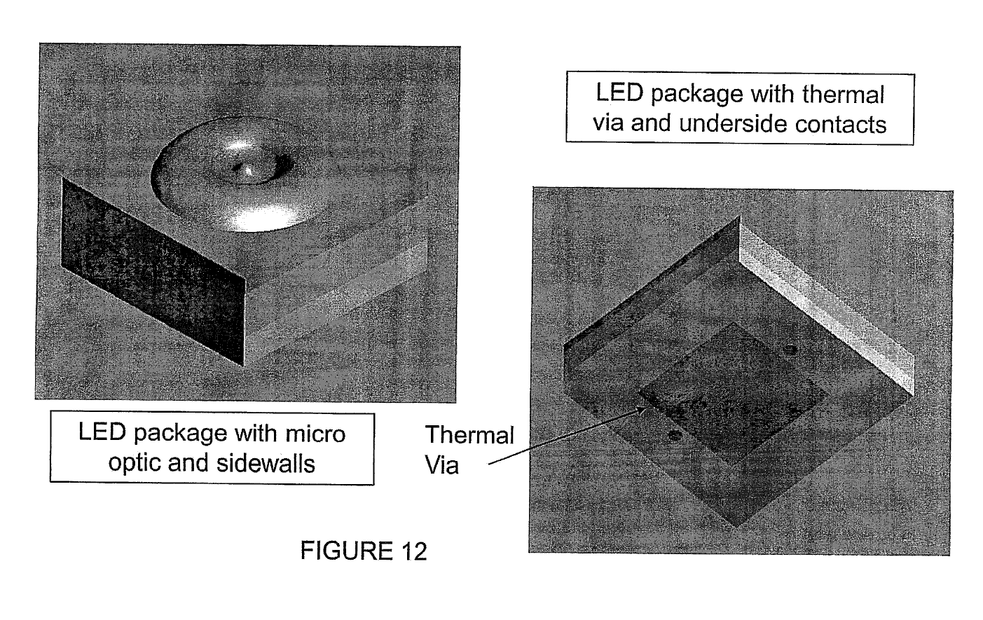

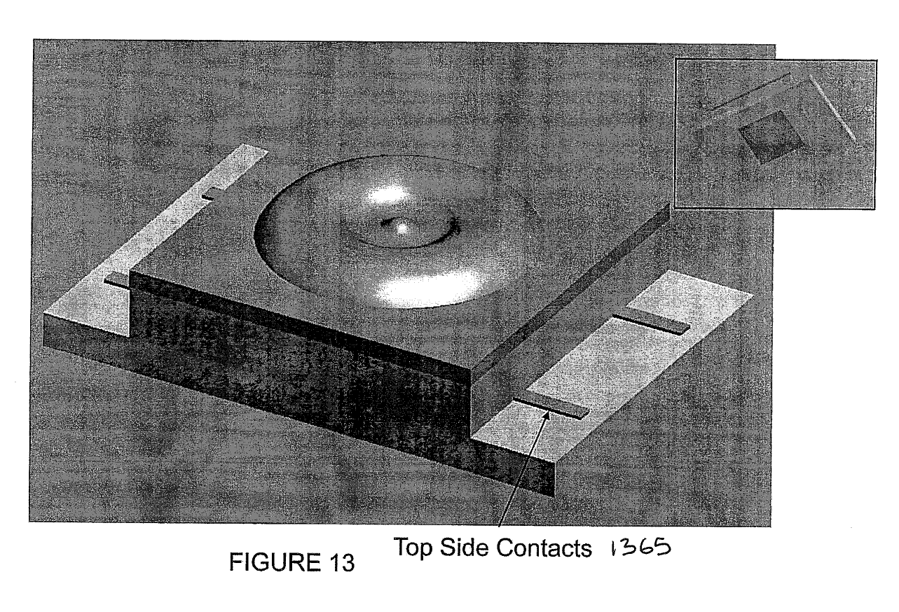

FIG. 12 shows isometric figures of an embodiment of an emitter package that includes underside contacts. In this embodiment, the perimeter of the lid, spacer, and substrate are co-extensive. By contrast, FIG. 13 shows isometric figures of an embodiment of an emitter package that includes top side contacts 1365. In this particular embodiment, the substrate extends beyond the perimeter of the spacer and lid. The top side contacts are located on the portion of the substrate that lies beyond the spacer and lid.

It should be noted that the perimeter of the bottom of the thermal via shown in the Figures is depicted as square. By controlling the manner in which the vias and/or plugs are formed (e.g., by controlling etch processes, masks, or cutting techniques), the thermal vias may have other shapes. The thermal vias may be circular, square, or other axi-symmetric shapes in cross section. The thermal vias may be non-symmetric in cross section.

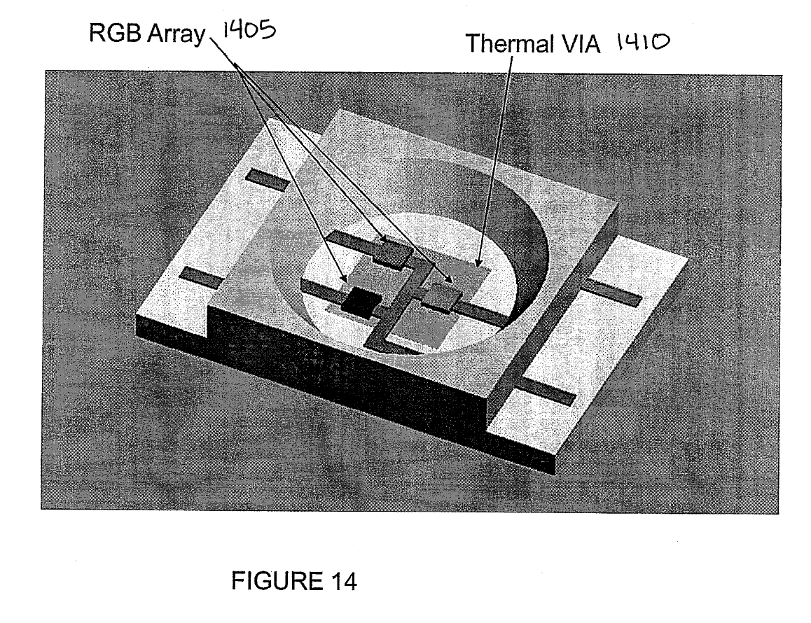

FIG. 14 shows an embodiment of an emitter package with shaped, reflective sidewalls and redistribution layer to an array of a plurality of emitters. In the embodiment shown, there are three emitters. In one embodiment, the emitters form an RGB LED array 1405. That is, each LED is configured to generate light in a narrow wavelength band around the colors red, green, and blue, respectively. Certainly other combinations of numbers and colors emitters are possible. However, it should be noted that each of the LEDs is mounted onto a common thermal via 1410. In other embodiments, each emitter may be mounted onto respective ones of a plurality of vias or some combination thereof depending on the heat and power dissipation requirements for the individual emitters.

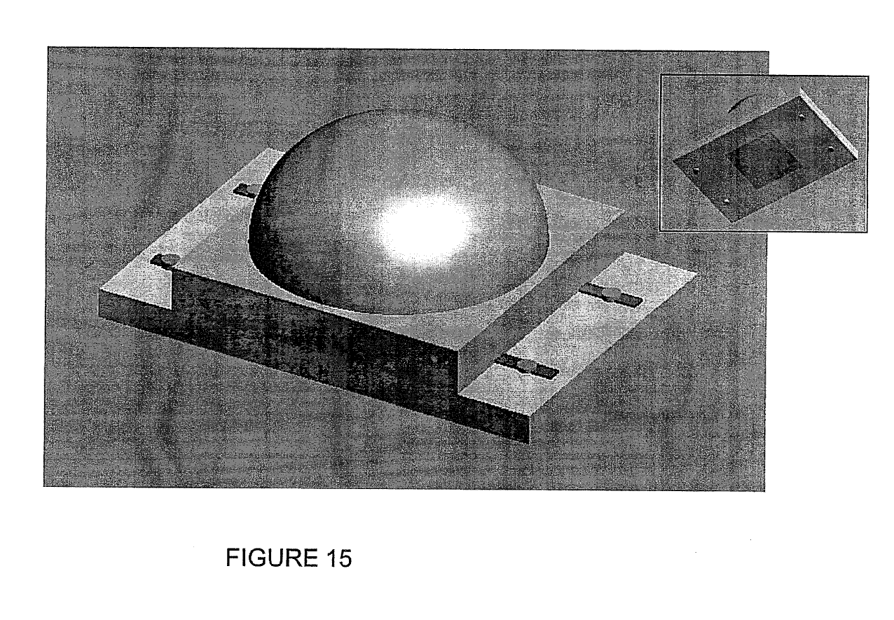

FIG. 15 shows an embodiment of an emitter package with a phosphor-polymer lens and top-side edge and underside contacts.

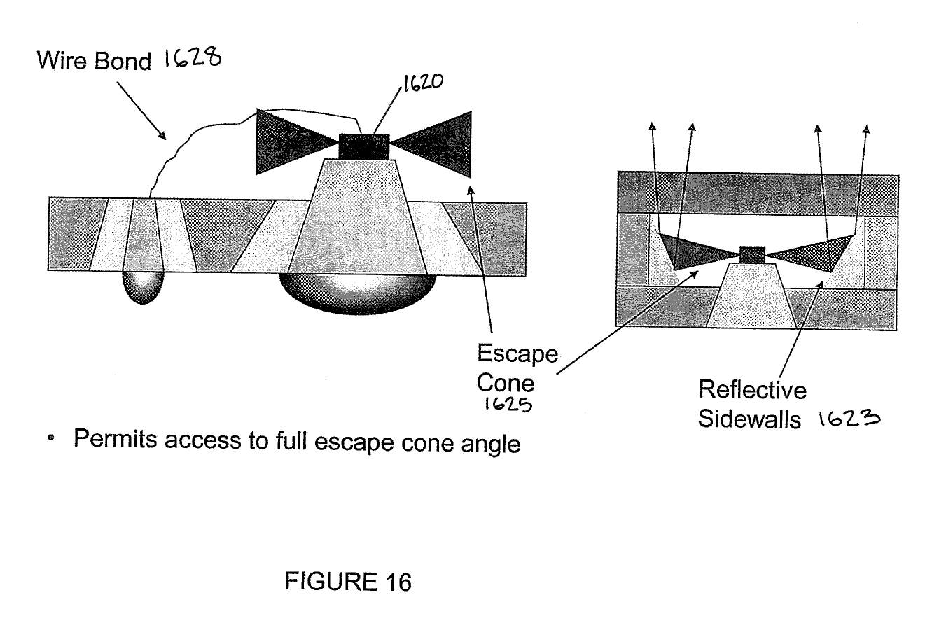

As described above, it is possible for the thermal vias to extend above a top surface of the substrate. This is illustrated again in FIG. 16, which shows an embodiment of an emitter package with an elevated emitter 1620. The light escape cone 1625 is raised above the top surface of the substrate to allow substantially all or a majority of the light to reach the reflective sidewalls 1623 of the spacer for redirection to the exterior of the package. In another aspect of the embodiment of FIG. 16, the emitter is electrically coupled to the electrical interface (in this case, a through silicon via) with a wire bond 1628. The wire bond provides an alternative connectivity to the redistribution layer described elsewhere herein.

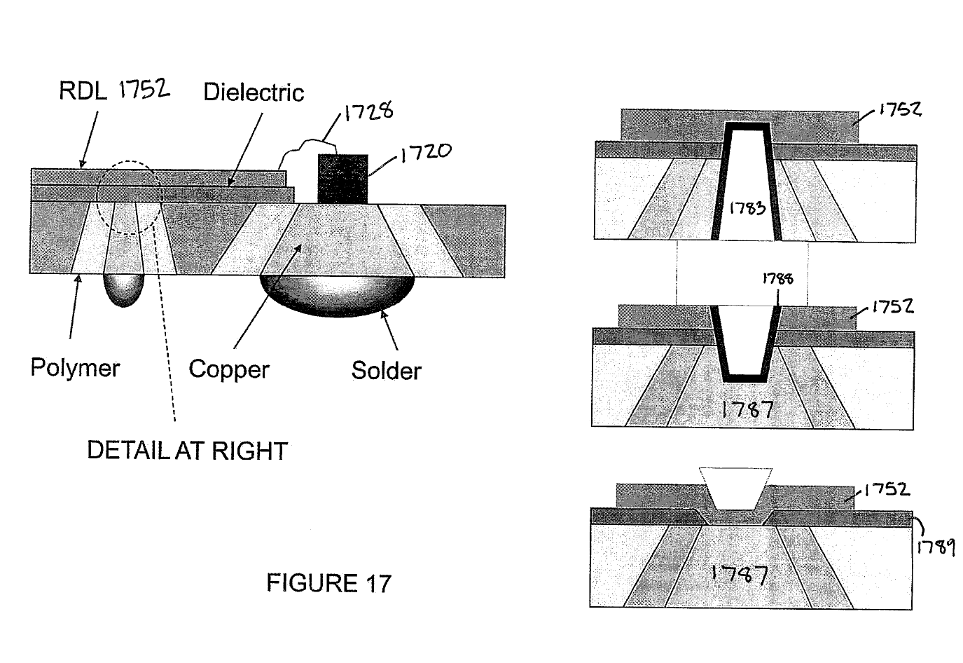

FIG. 17 shows an embodiment of an emitter package where electrical connectivity is established through a combination of a wire bond 1728 and a redistribution layer (RDL) 1752. In this particular embodiment, redistribution layer 1752 is not directly coupled to the emitters 1720, but instead relies on a separate wire bond 1728.

FIG. 17 also shows that a plurality of different connections may be used at the interface between the electrical via and the redistribution layer 1752. In one embodiment, the connection between the via and RDL 1752 is created with a bottom-up via 1783 as described previously. In another embodiment, the connection between the via and RDL 1752 is created with a top-down connection in which a metal layer 1788 is formed into a filled via 1787 formed within the substrate. In another embodiment, the connection between the via and RDL 1752 is created with a top-down connection in which a metal layer 1789 is formed so as to abut, but not penetrate a filled via 1787 formed within the substrate.

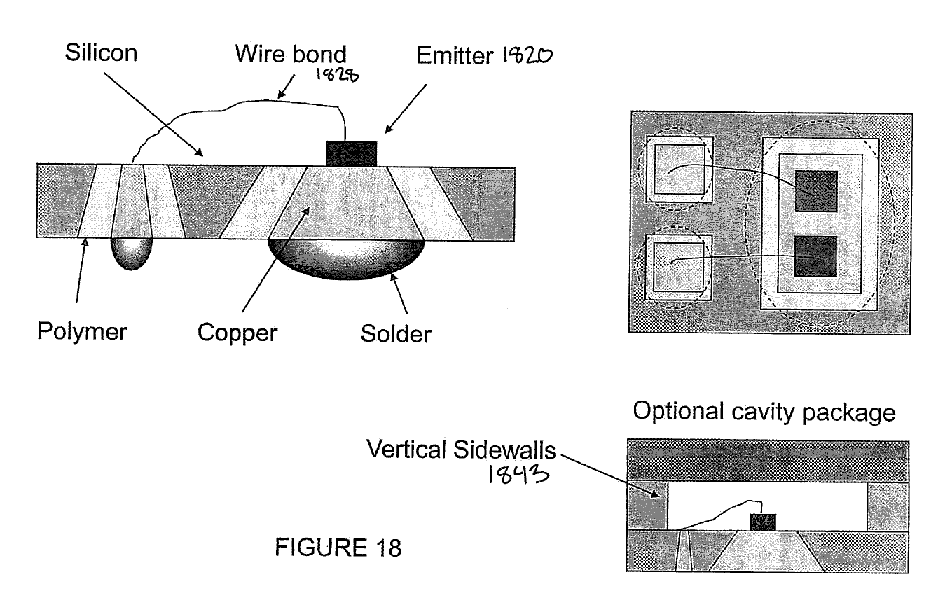

FIG. 18 shows an embodiment of an emitter package where the emitter 1820 sits substantially flush with a top surface of the substrate wafer and electrical connectivity is established solely with a wire bond 1828 to an electrical through silicon via. FIG. 18 further shows an embodiment that includes a spacer that does not include sloped or tapered sidewalls, but vertical sidewalls 1843 instead.

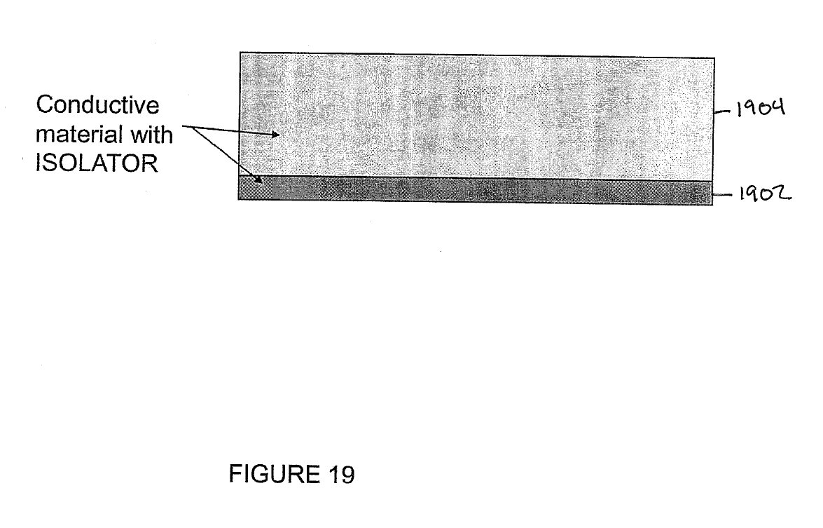

FIG. 19 shows a first step in a process for manufacturing a wafer level emitter package with integral thermal vias. Initially, an isolator 1902 is applied to one side of a conductive sheet 1904. As discussed above, the conductive material 1904 may be copper, aluminum, or other metals or alloys thereof. In other embodiments, the material may include a bulk material with conductive fillers. The isolator 1902 may be epoxy type (e.g., solder mask material), other polymers, or other materials suitable to isolate subsequent etching steps to the conductive material. The isolator may be applied by spinning, dipping, screen print, lamination or other processes. The isolator may not be necessary in all instances such as when subsequent etching or cutting does not pass substantially through the full thickness of the conductive material.

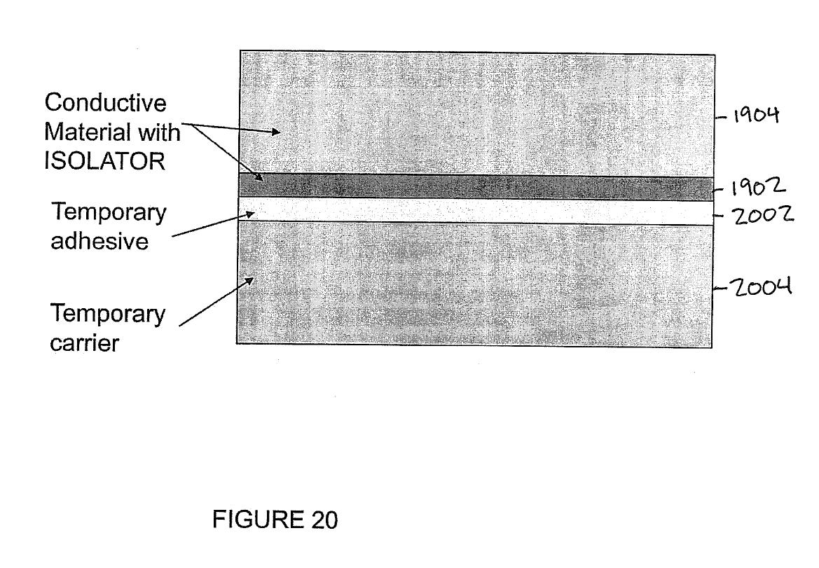

In FIG. 20, the process continues with the temporary bonding of the conductive material 1904 to a temporary carrier 2004 using a temporary adhesive 2002. In one embodiment, temporary carrier 2004 is made of silicon or glass or other rigid or semi-rigid material. In another embodiment, temporary carrier 2004 may be a polymer or other compliant material. In any event, temporary adhesive 2992 may be applied by spinning, dipping, film or other approaches.

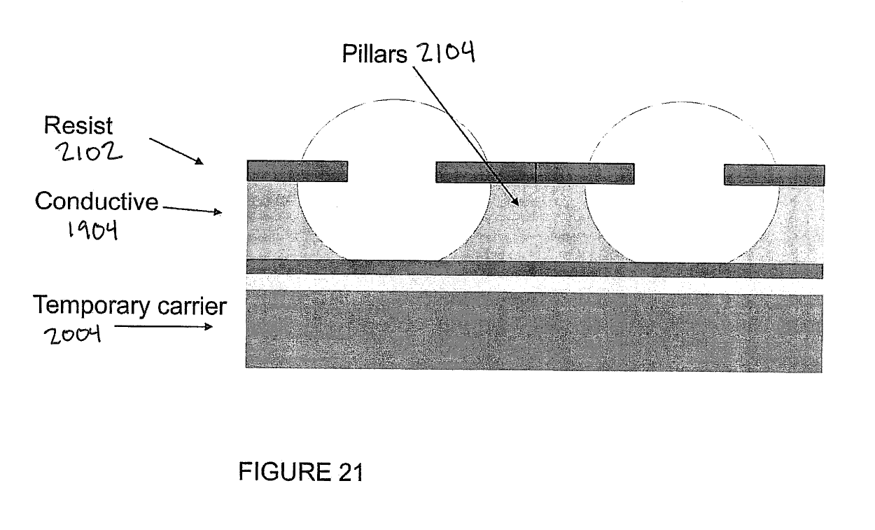

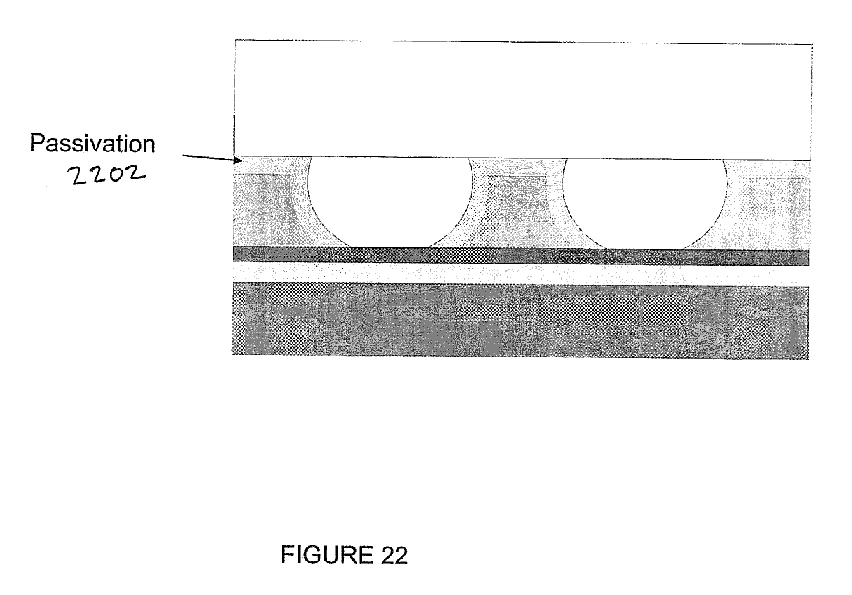

In the next step of this example embodiment, shown in FIG. 21, a resist layer 2102 is applied on top of the conductive material 1904. Resist layer 2102 is patterned such that conductive material 1904 can be etched to form a plurality of pillars 2104. In a subsequent step shown in FIG. 22, the resist layer 2102 is removed and an optional passivation layer 2202 is applied onto the etched conductive material. The passivation material may be an epoxy type polymer or other insulator as described above. Further, the passivation material can be applied by electrophoresis, spinning, dipping, spraying or other techniques.

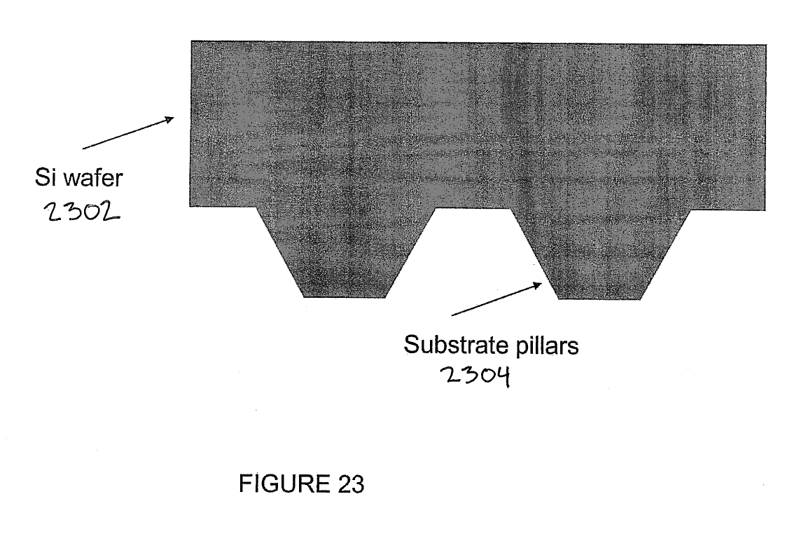

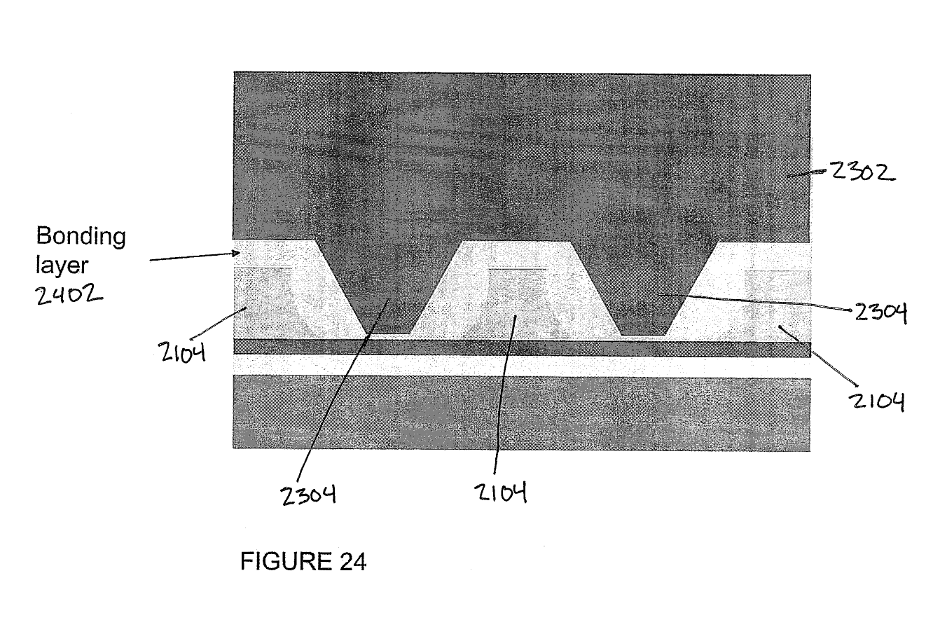

In parallel to the process steps shown in FIGS. 19-22, a silicon substrate 2302 may be processed according to FIG. 23. A dry or wet etching process may be used to produce a plurality of substrate pillars 2304. Generally, substrate pillars 2304 have a similar pitch to the conductive material pillars 2104 so that the two wafers can be brought together as shown in FIG. 24. Specifically, FIG. 24 shows conductive material wafer 1904 bonded to substrate wafer 2302 with substrate pillars 2304 staggered relative to conductive pillars 2104. The two wafers may be bonded using an epoxy adhesive 2402, such as with commercially available bonding tools. Epoxy 2402 may be applied to one or both of the wafers and can be applied by electrophoresis, spinning, dipping, spraying or other techniques.

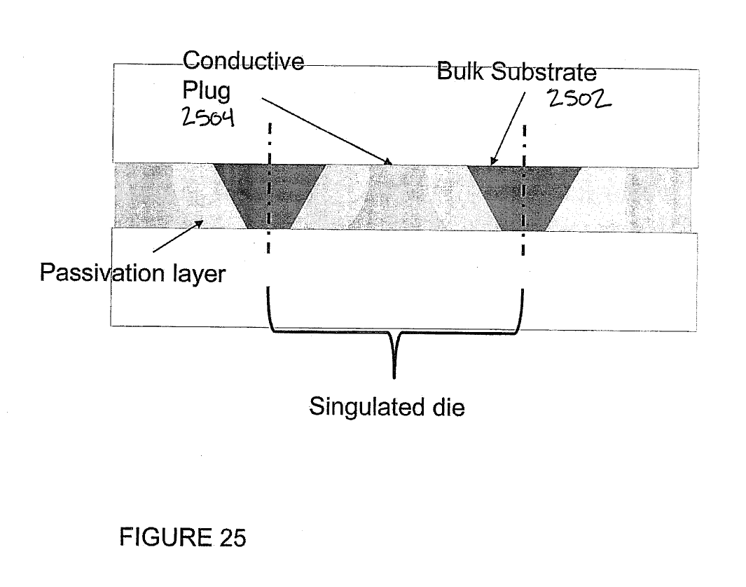

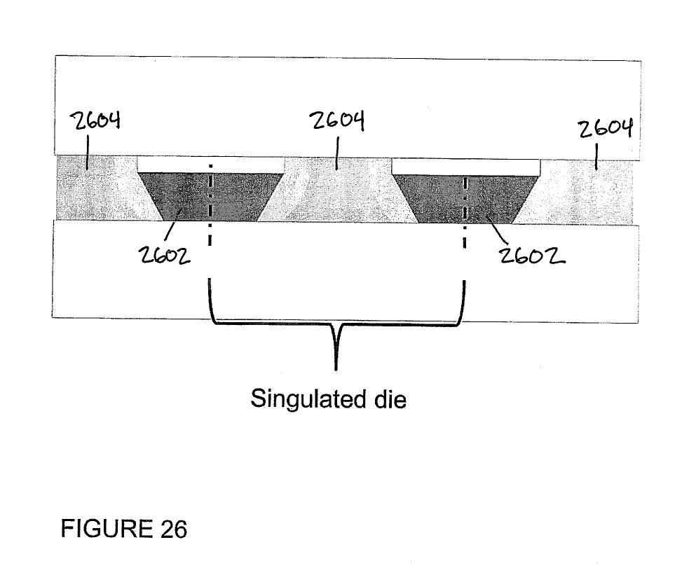

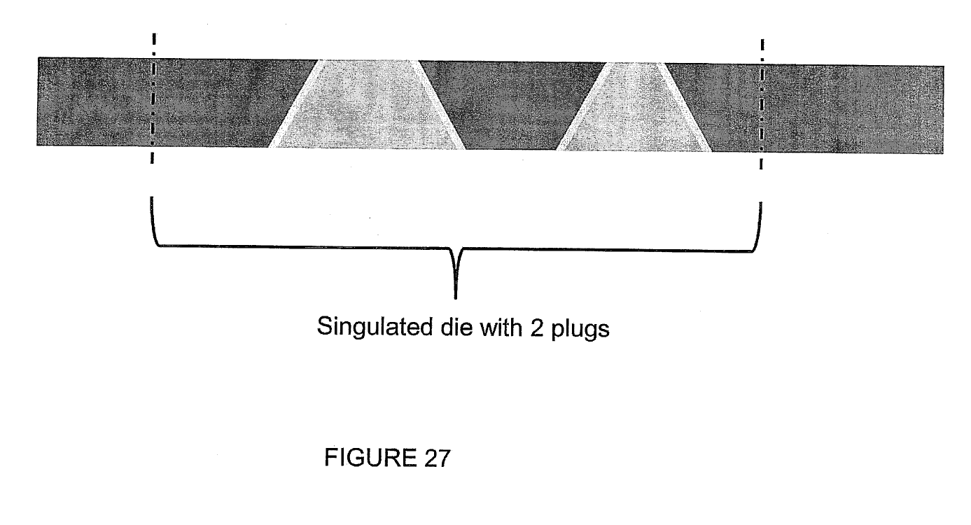

In the next step of the exemplary process shown in FIG. 25, the substrate wafer is polished or removed by a grinder or polisher. Next, the temporary carrier is removed, which may require heating or other catalyst to remove the bonded materials. After the temporary carrier is removed, the conductive plugs 2504 are additionally polished. In one embodiment, the substrate material 2502 and conductive plugs 2504 are polished to the same thickness. In an alternative embodiment shown in FIG. 26, a subsequent etching of the substrate material will produce the particular configuration where the conductive plugs 2604 extend above a top surface of the bulk substrate material 2602. As discussed, the etching may be a dry etch or wet etch, particularly where the bulk material is silicon. Lastly, as shown in FIG. 27, the individual die may be singulated using known dicing, ablating, or laser cutting techniques. In one embodiment, each die includes a single conductive via or plug. In other embodiments, each die can include multiple conductive vias or plugs as shown in FIG. 27.

The various embodiments of a thermal plug or thermal via provides an improved capacity to extract heat from the emitter(s). This capacity is due in part to the relative cross sectional area of the thermal via and in part to the thermal conductivity of the thermal via. Generally, a rate at which thermal energy is conducted through a material is given by:

$${q}_{x} = - kA \frac{d T}{d x}$$

where qx is the heat transfer or energy in transit due to a temperature difference (dT) along the direction (dx) of the thermal via. Also, k is the thermal conductivity of the thermal via and A is the cross sectional area of the via. This equation shows the proportionality of the capacity to extract heat to the area and conductivity of the thermal via. Thus, it is useful to maximize area and conductivity. The thermal vias shown herein have a larger area than the electrical vias. Consequently, even though both the electrical vias and thermal vias may be fabricated using a common material, the size difference between the two determines that the thermal via has a greater capacity to extract heat. Also, representative numbers for the thermal conductivity of various materials is shown below in Table I.

TABLE I
Representative Thermal Conductivities

| Material | k (W/m-K) |
|---|---|
| Copper | 400 |
| Silicon | 150 |
| Alumina | 30-40 |
| Glass | 1 |

Thus, one can see that a thermal via that maximizes cross section and thermal conductivity will have desirable heat extraction capabilities.

In the foregoing specification, embodiments of the invention have been described with reference to numerous specific details that may vary from implementation to implementation. The specification and drawings are, accordingly, to be regarded in an illustrative rather than a restrictive sense. The sole and exclusive indicator of the scope of the invention, and what is intended by the applicants to be the scope of the invention, is the literal and equivalent scope of the set of claims that issue from this application, in the specific form in which such claims issue, including any subsequent correction.

1. A package comprising:
a substrate; and
a thermal via that extends substantially through the thickness of the substrate;
said thermal via being made of a material possessing a higher thermal conductivity than said substrate;
wherein said substrate and said thermal via are fabricated at a wafer scale by coupling a pillar of a conductive material wafer with an aperture of a substrate wafer.

2. The package of claim 1, wherein said substrate is made of silicon and wherein said thermal via is made of one of: (a) conductive, (b) aluminum, (c), silver, and (d) gold.

3. The package of claim 1, wherein said thermal via is wider at an exterior of the package than said thermal via is at an interior of the package on which a light emitting diode is to be positioned.

4. The package of claim 1, wherein said thermal via is tapered at an angle between 30 and 60 degrees.

5. The package of claim 1, wherein said thermal via is insulated from said substrate by an insulating layer.

6. The package of claim 5, wherein said insulating layer is made of one of: (a) polymer, (b) plastic, (c) rubber, and (d) silicone.

7. The package of claim 1, wherein said thermal via is fabricated along with a plurality of thermal vias on a first wafer scale component; and wherein said substrate is fabricated with a plurality of apertures, into which said plurality of thermal vias fit, on a second wafer scale component that is separate from said first wafer scale component.

8. The package of claim 1, further comprising:
a spacer positioned on a top surface of said substrate;
said spacer having a thickness that is at least as great as a height of a light-emitting diode that is to be positioned on a top surface of said thermal via;
said spacer having a bottom opening that permits said light-emitting diode to contact said thermal via;
said spacer having a top opening that permits light from said light-emitting diode to emanate from said package;
said spacer including an interior space that opens at said top opening and at said bottom opening.

9. The package of claim 8, wherein said interior space of said spacer is tapered at an angle of substantially 45 degrees between said top opening and said bottom opening.

10. The package of claim 8, wherein said interior space of said spacer is bordered by surfaces that are curved; wherein said surfaces are curved to form a section of a parabola at whose foci said light-emitting diode is to be positioned.

11. The package of claim 8, wherein said interior space of said spacer is bordered by surfaces that are coated with a reflective coating.

12. The package of claim 8, wherein said spacer is made of liquid crystal polymer.

13. The package of claim 8, wherein said thermal via extends above a top surface of said substrate by a height that makes a top surface of said thermal via position a light emitting diode at a focus of a parabolic surface formed by interior walls of said spacer under circumstances in which said light-emitting diode is placed on said top surface of said thermal via.

14. The package of claim 8, wherein said package is formed at least in part by dicing a wafer scale component on which a plurality of other packages, having the same features as said package, have also been formed.

15. The package of claim 1, further comprising:
a plurality of light-emitting diodes of different colors mounted on said thermal via.

16. A method for packaging a particular light-emitting diode (LED), said method comprising:
populating a plurality of LED dies on a substrate wafer;
forming a separate thermal via through said substrate wafer at each position of each LED die of said plurality of LED dies, including coupling a pillar of a conductive material wafer with an aperture of the substrate wafer; and
after forming said thermal vias, singulating said plurality of LED dies from said substrate wafer, thereby packaging at least said particular LED;
said thermal vias being made of a material possessing a higher thermal conductivity than said substrate wafer.

17. The method of claim 16, wherein singulating said substrate wafer comprises one of:
(a) dicing said substrate wafer, (b) ablating said substrate wafer, and (c) laser-cutting said substrate wafer.

18. The package of claim 1, wherein the substrate and thermal via are further fabricated at wafer scale by respectively removing conductive material wafer material around the pillar and removing substrate material to create the aperture to approximately match the pillar.

19. The package of claim 1, wherein the thermal via is further fabricated at wafer scale by etching.

20. The package of claim 1, wherein the aperture is further fabricated at wafer scale by etching.

21. The package of claim 1, wherein the thermal via is further fabricated at wafer scale by removing material around the pillar to approximately match the aperture.

22. The package of claim 1, wherein the aperture is further fabricated at wafer scale by removing substrate material to approximately match the pillar.

23. The package of claim 1, wherein the thermal via comprises an approximately frusto-conical shape.

24. The package of claim 23, wherein the aperture comprises an approximately frusto-conical shape that approximately matches the thermal via.

25. The package of claim 1, further comprising a joining material between the thermal via and the aperture.

26. The package of claim 25, wherein the joining material comprises a polymer.

27. The package of claim 1, wherein the thermal via and aperture are joined in direct contact.

28. The package of claim 1, further comprising a LED mounted on said thermal via.

29. The method of claim 16, further comprising fabricating the thermal via at wafer scale including removing substrate material to create the aperture to approximately match the pillar of the conductive material wafer.

30. The method of claim 16, further comprising fabricating the thermal via at wafer scale including creating an aperture having an approximately frusto-conical shape.

31. The method of claim 16, further comprising fabricating the thermal via at wafer scale including etching the substrate to create the aperture.

32. The method of claim 16, further comprising fabricating the thermal via at wafer scale including etching the conductive material wafer to create the pillar.

33. The method of claim 23, wherein the aperture comprises an approximately frusto-conical shape that approximately matches the pillar.

34. The method of claim 16, further comprising applying a third material to the aperture to join the pillar and the aperture to form the thermal via.

35. The method of claim 34, wherein the third material comprises a polymer.

36. The method of claim 16, further comprising joining the conductive material pillar and aperture in direct contact.

37. The method of claim 16, further comprising mounting a LED on said thermal via.

38. A method of forming a package configured to support a light-emitting diode (LED), said method comprising:
providing a substrate wafer and a conductive material wafer;
forming a separate aperture through said substrate wafer to form a LED support die at each position where a LED is to be mounted;
coupling the conductive material wafer with the substrate wafer including aligning multiple conductive material pillars of the conductive material wafer with multiple approximately matching apertures of the substrate wafer to form thermal vias at positions where LEDs are to be mounted; and
said thermal vias being made of a material possessing a higher thermal conductivity than said substrate wafer.

39. The method of claim 38, further comprising mounting LEDs on said thermal vias.

40. The method of claim 39, further comprising singulating said substrate wafer including (a) dicing said substrate wafer, (b) ablating said substrate wafer, or (c) laser-cutting said substrate wafer.

41. The method of claim 38, further comprising fabricating the thermal via at wafer scale including removing substrate material and creating the aperture.

42. The method of claim 41, wherein the creating of the aperture comprises approximately matching a conductive material pillar of the conductive material wafer.

43. The method of claim 38, further comprising fabricating the thermal via at wafer scale including creating the aperture to have an approximately frusto-conical shape.

44. The method of claim 38, further comprising fabricating the thermal via at wafer scale including etching the substrate to create the aperture.

45. The method of claim 38, further comprising fabricating the thermal via at wafer scale including etching the conductive material wafer to create a conductive material pillar.

46. The method of claim 45, wherein the aperture comprises an approximately frusto-conical shape that approximately matches the pillar.

47. The method of claim 38, further comprising applying a third material to the aperture to join a conductive material pillar and an aperture to form a thermal via.

48. The method of claim 47, wherein the third material comprises a polymer.

49. The method of claim 38, further comprising joining a conductive material pillar and aperture in direct contact.

50. The package of claim 1, wherein the conductive material wafer comprises a copper wafer.

51. The package of claim 50, wherein the copper wafer comprises multiple copper pillars.

52. The package of claim 51, wherein the multiple copper pillars comprise etched pillars.

53. The method of claim 16, wherein the conductive material wafer comprises a copper wafer.

54. The package of claim 53, wherein the copper wafer comprises multiple copper pillars.

55. The package of claim 54, wherein the multiple copper pillars comprise etched pillars.

56. The method of claim 38, wherein the conductive material wafer comprises a copper wafer.

57. The package of claim 56, wherein the copper wafer comprises multiple pillars.

58. The method of claim 57, wherein the multiple pillars comprise etched pillars.
